(19) United States
(12) Patent Application Publication
(10) Pub. No.: US 2012/0180855 A1
(43) Pub. Date: Jul. 19, 2012

(54) PHOTOVOLTAIC DEVICES AND METHODS OF FORMING THE SAME

(75) Inventors: Fan Yang, Sunnyvale, CA (US); Sijin Han, Milpitas, CA (US)

(73) Assignee: QUALCOMM MEMS TECHNOLOGIES, INC., San Diego, CA (US)

(21) Appl. No.: 13/009,546

(22) Filed: Jan. 19, 2011

(51) Int. Cl. H01L 31/06; H01L 31/18

(52) U.S. Cl. 136/255; 438/73; 257/E31.126

(57) ABSTRACT

This disclosure provides photovoltaic apparatus and methods of forming the same. In one implementation, a photovoltaic device includes a transparent insulator, a first thin film solar subcell disposed on a first surface of the transparent insulator, and a second thin film solar subcell disposed on a second surface of the transparent insulator opposite the first surface. The first solar subcell is configured to receive ambient light, and the second solar subcell is configured to receive a portion of light that propagates through the first solar subcell. The second solar subcell includes a first electrode including a conductive reflective layer configured to reflect light that propagates through a photovoltaic structure of the second subcell back toward the first solar subcell.

### TECHNICAL FIELD

This disclosure relates to photovoltaic devices.

### DESCRIPTION OF THE RELATED TECHNOLOGY

For over a century fossil fuels such as coal, oil, and natural gas have provided the main source of energy in the United States. The need for alternative sources of energy is increasing. Fossil fuels are a non-renewable source of energy that is depleting rapidly. The large scale industrialization of developing nations such as India and China has placed a considerable burden on available fossil fuel. In addition, geopolitical issues can quickly affect the supply of such fuel. Global warming is also of greater concern in recent years. A number of factors are thought to contribute to global warming; however, widespread use of fossil fuels is presumed to be a major contributor to global warming. Thus, there is a need to find a renewable and economically viable source of energy that is also environmentally safe. Solar energy is an environmentally safe renewable source of energy that can be converted into other forms of energy such as heat and electricity.

Photovoltaic cells convert optical energy to electrical energy and thus can be used to convert solar energy into electrical power. Photovoltaic cells can be made very thin and modular, and can range in size from about a few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Additionally, photovoltaic cells can be used in a wide range of applications, such as providing power to satellites and other spacecraft, providing electricity to residential and commercial properties, charging automobile batteries, and powering mobile devices, such as smart phones or personal computers.

While photovoltaic devices have the potential to reduce reliance upon hydrocarbon fuels, the widespread use of photovoltaic devices has been hindered by a variety of factors, including energy inefficiency. Accordingly, there is a need for photovoltaic devices having improved power efficiency. Moreover, there is a need for photovoltaic devices that can operate efficiently over a wide range of lighting conditions.

### SUMMARY

The systems, methods and devices of the disclosure each have several innovative aspects, no single one of which is solely responsible for the desirable attributes disclosed herein.

One innovative aspect of the subject matter described in this disclosure can be implemented in a solar cell device including a transparent insulator, a thin film first solar subcell disposed on a first surface of the transparent insulator, and a thin film second solar subcell disposed on a second surface of the transparent insulator, the second surface on an opposite side of the transparent insulator than the first surface. The first solar subcell is configured to receive ambient light, and the second solar subcell is configured to receive a portion of light that propagates through the first solar subcell. The second solar subcell includes a first electrode including a conductive reflective layer configured to reflect light that propagates through a photovoltaic structure of the second subcell back toward the first solar subcell.

In some implementations, the first solar subcell is characterized by a first absorption spectrum and the second solar subcell is characterized by a second absorption spectrum different from the first absorption spectrum. According to some implementations, the transparent insulator prevents chemical reactions between the first and second solar sub cells.

Another innovative aspect of the subject matter described in this disclosure can be implemented in a solar power system including a stack of thin film solar subcells. The stack of thin film solar subcells includes an optically transparent insulator having a first side and an opposite second side, a thin film first solar subcell disposed on a first side of the insulator, and a thin film second solar subcell disposed on a second side of the insulator. The first solar subcell includes a first conductive layer defining a first electrical terminal, a first photovoltaic structure, and a second conductive layer defining a second electrical terminal. The first and second electrical terminals contact opposite sides of the first photovoltaic structure and are configured to provide electrical power generated by the first photovoltaic structure to an external circuit when the first solar subcell is illuminated with light. The second solar subcell includes a third conductive layer defining a third electrical terminal, a second photovoltaic structure, and a fourth conductive layer defining a fourth electrical terminal. The third and fourth electrical terminals contact opposite sides of the second photovoltaic structure and are configured to provide electrical power generated by the second photovoltaic structure when the second solar subcell is illuminated with light. The insulator is optically transparent to a portion of light absorbed by the second solar subcell.

Another innovative aspect of the subject matter described in this disclosure can be implemented in method of forming a thin film solar cell device. The method includes forming a first conductive layer on a first surface of a transparent substrate, forming a first photovoltaic structure over the first conductive layer, forming a second conductive layer over the first photovoltaic structure, forming a third conductive layer on a second surface of the transparent substrate, forming a second photovoltaic structure over the third conductive layer, and forming a fourth conductive layer over the second photovoltaic structure. The second surface is on an opposite side of the transparent substrate than the first surface.

Another innovative aspect of the subject matter described in this disclosure can be implemented in solar cell device including a transparent insulator, a first means for receiving ambient light, and a second means for receiving ambient light. The transparent insulator includes a first and second surface, the second surface on an opposite side of the transparent insulator than the first surface. The first light receiving means includes a thin film solar subcell disposed on the first surface of the transparent insulator. The second light receiving means includes a thin film second solar subcell disposed on the second surface of the transparent insulator and is configured to receive a portion of light that propagates through the first light receiving means. The second light receiving means includes a first reflective electrode configured to reflect light that propagates through the photovoltaic structure of the second light receiving means back toward the first light receiving means.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a photovoltaic cell providing power to a load.

FIG. 2A shows an example of one implementation of a photovoltaic device.

FIG. 2B shows a graph of one example of quantum efficiency versus wavelength of a photovoltaic device including first and second photovoltaic subcells.

FIG. 3 shows an example of a flow diagram illustrating a manufacturing process for a photovoltaic device.

FIGS. 4A-4G show examples of cross-sectional schematic illustrations of various stages in a method of making a photovoltaic device.

FIGS. 5A-5C show examples of cross-sections of varying implementations of photovoltaic devices.

### DETAILED DESCRIPTION

Photovoltaic devices having a first photovoltaic subcell, a second photovoltaic subcell, and a transparent substrate are disclosed. The first photovoltaic subcell is disposed on a first surface of the transparent substrate and can receive light. The second photovoltaic cell is disposed on a second surface of the transparent substrate opposite to the first surface, and can receive a portion of light that passes through the first photovoltaic subcell. The first and second photovoltaic subcells each include separate electrodes for providing power or current to one or more loads, for example, to an electrical device, to an electrical power system which then provides power to other electrical devices, and/or to an electrical power storage system. By providing separate electrodes, the first and second subcells can be configured to electrically operate in parallel, thereby avoiding limiting the current of the photovoltaic device to the smaller of the photocurrents generated by the first or second subcells. In certain implementations, the second subcell can include a reflector which is positioned and configured to reflect light unabsorbed by the second photovoltaic subcell back toward the first photovoltaic subcell to increase the amount of power generated from a given amount of incident light (e.g., power efficiency) on the photovoltaic device.

Particular implementations of the subject matter described in this disclosure can be implemented to increase power efficiency of a photovoltaic device. Additionally, some implementations can be used to improve robustness of a photovoltaic device to variations in solar spectrum, such as variations that can occur at high altitude, on cloudy or overcast days, during winter or spring, and/or at dusk or dawn. Furthermore, according to some implementations, providing first and second photovoltaic subcells on opposite sides of a transparent substrate facilitates the manufacture of subcells having vastly different chemistries, thereby increasing flexibility in design of the photovoltaic device. Enhancing flexibility in the design of the photovoltaic device permits a broader selection of manufacturing materials for the first and second photovoltaic subcells, including materials having absorption spectrums that are more complimentary relative to existing tandem junction solar cells.

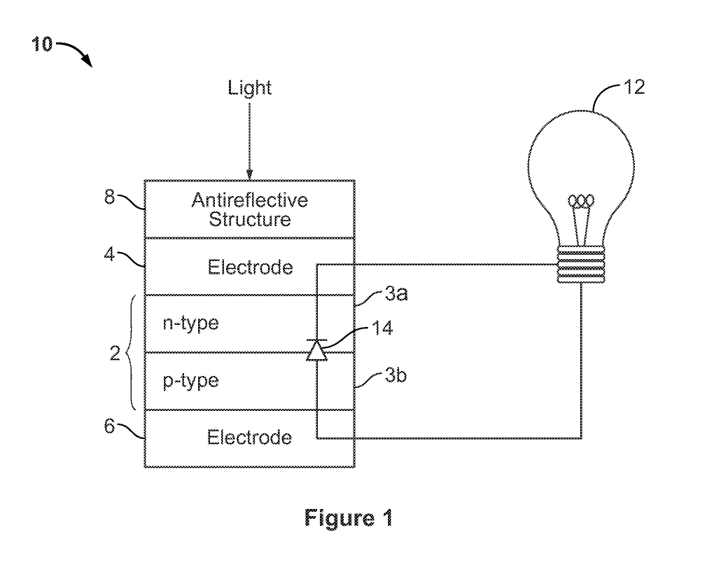

FIG. 1 shows an example of a photovoltaic cell 10 providing power to a load 12. The photovoltaic cell 10 includes a p-n junction 2, a first electrode 4, a second electrode 6, and an antireflective structure 8. The p-n junction 2 includes an n-type structure 3a and a p-type structure 3b. The first electrode 4 is disposed between the antireflective structure 8 and the n-type structure 3a, and the p-type structure 3b is disposed between the n-type structure 3a and the second electrode 6.

The first and second electrodes 4, 6 can be any suitable conductor. For example, the first and/or second electrodes 4, 6 can be a transparent conductor, including, for example, a transparent conducting oxide (TCO) of zinc oxide (ZnO) or indium tin oxide (ITO). A TCO or other transparent conductor in the photovoltaic cell 10 can provide electrical connectivity to the p-n junction 2, while permitting light to pass through the first and/or second electrodes 4, 6 and reach the p-n junction 2. However, the first electrode 4 and/or the second electrode 6 need not be transparent. For example, the first electrode 4 can formed of an opaque material and can include one or more openings that provide a path for light to reach the p-n junction 2. Additionally, the second electrode 6 can be configured as a reflector to reflect light that passes through the first electrode 4 and the p-n junction 2 back toward the p-n junction 2.

The p-n junction 2 can be formed from a wide variety of materials, including, for example, silicon (Si), germanium (Ge), cadmium telluride (CdTe), and/or copper indium gallium (di)selenide (CIGS). The p-n junction 2 can operate as a photodiode 14, which can convert light energy into electrical energy or current. When the p-n junction 2 is illuminated with light, photons from the light can transfer energy to the p-n junction 2, which can result in the creation of electron-hole pairs. For example, photons having energy greater than the band-gap of the p-n junction 2 can generate electron-hole pairs within the p-n junction 2 by band-to-band excitation and/or high-energy photons can generate electron-hole pairs by impact ionization or via recombination-generation centers within the lattice of the p-n junction 2. When photons create electron-hole pairs within or near the depletion region of the p-n junction 2, the electric field of the depletion region can sweep the electrons and holes to the first and second electrodes of the photovoltaic cell 10, thereby generating a photocurrent. The photocurrent can be used to provide power to any suitable load, such as the illustrated load 12.

In certain implementations, the photovoltaic cell 10 can include the antireflective structure 8 disposed on a surface of the first electrode 4 opposite the p-n junction 2 (e.g., a incident light surface). The antireflective structure 8 can reduce the amount of light reflected off of the photovoltaic cell 10, thereby increasing the amount of light reaching the p-n junction 2 and the overall power efficiency of the cell.

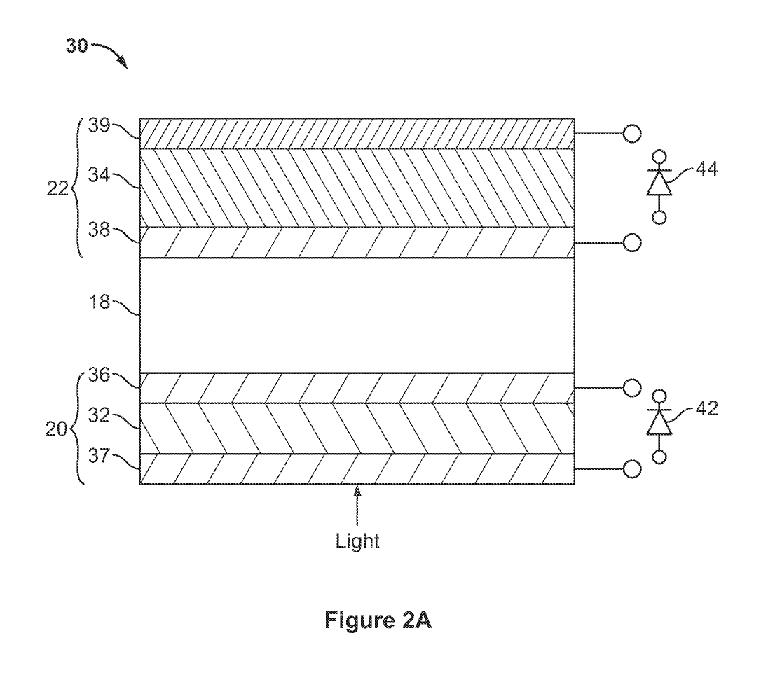

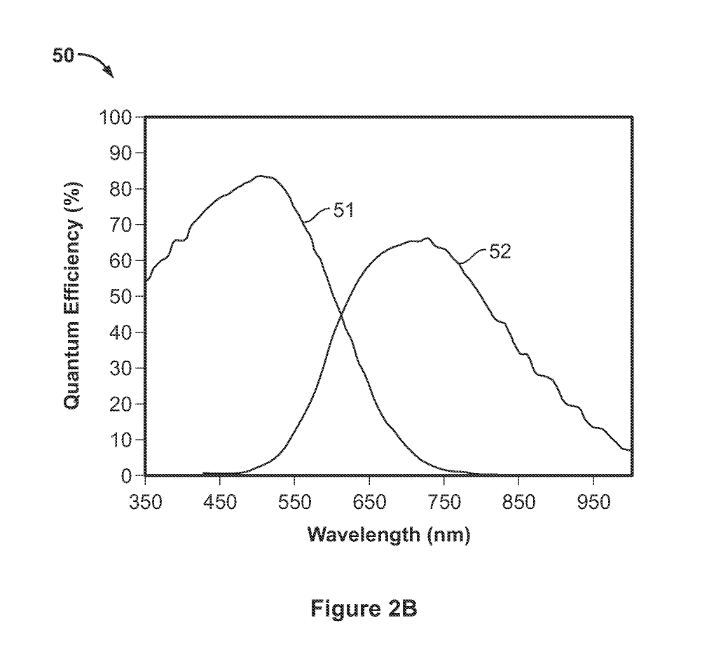

FIG. 2A shows an example of one implementation of a photovoltaic device 30. The photovoltaic device 30 includes a first photovoltaic subcell 20 formed on a first surface of a transparent insulator or substrate 18 and a second photovoltaic subcell 22 formed on a second surface of the transparent substrate 18 opposite to the first surface.

The first photovoltaic subcell 20 includes a first photovoltaic structure 32, and includes first and second electrodes 36, 37 as electrical terminals of the first photovoltaic subcell 20. In this implementation, the first electrode 36 is disposed adjacent to the first surface of the transparent substrate 18, the first photovoltaic structure 32 is disposed adjacent to the first electrode 36, and the second electrode 37 is disposed adjacent to the first photovoltaic structure 32 opposite to the first electrode 36.

Similarly, the second photovoltaic subcell 22 includes a second photovoltaic structure 34, and third and fourth electrodes 38, 39 as electrical terminals of the second photovoltaic subcell 22. In this implementation, third electrode 38 is disposed adjacent to the second surface of the transparent substrate 18, the second photovoltaic structure 34 is disposed adjacent to the third electrode 38, and the fourth electrode 39 is disposed adjacent to the second photovoltaic structure 34 opposite to the third electrode 38.

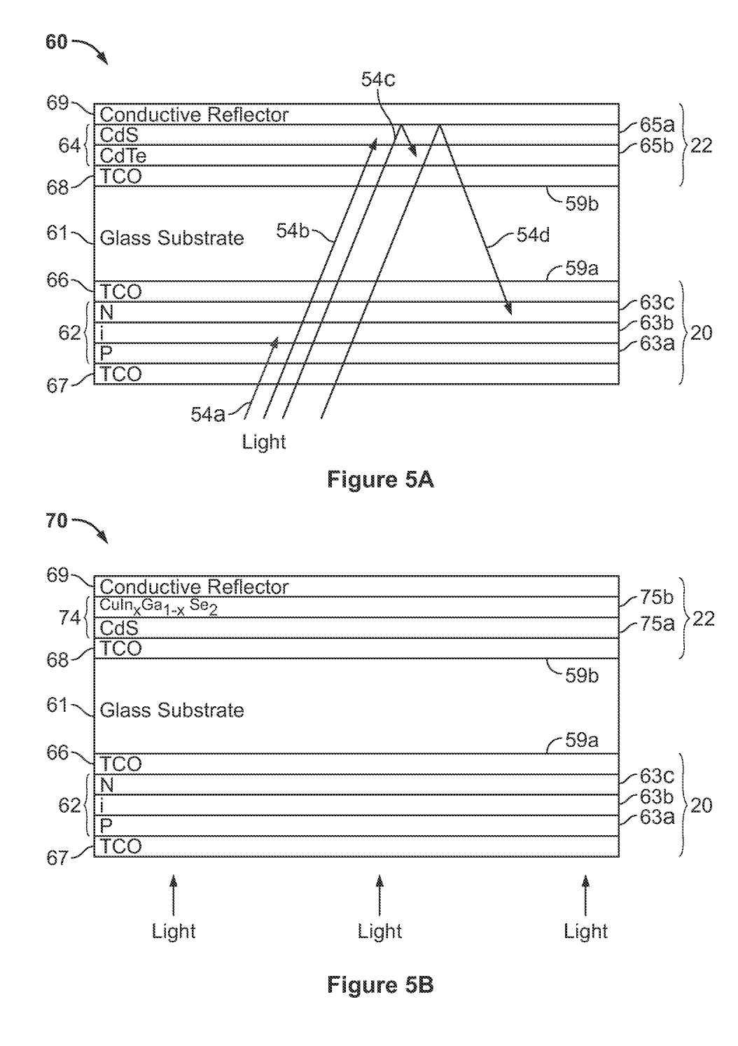

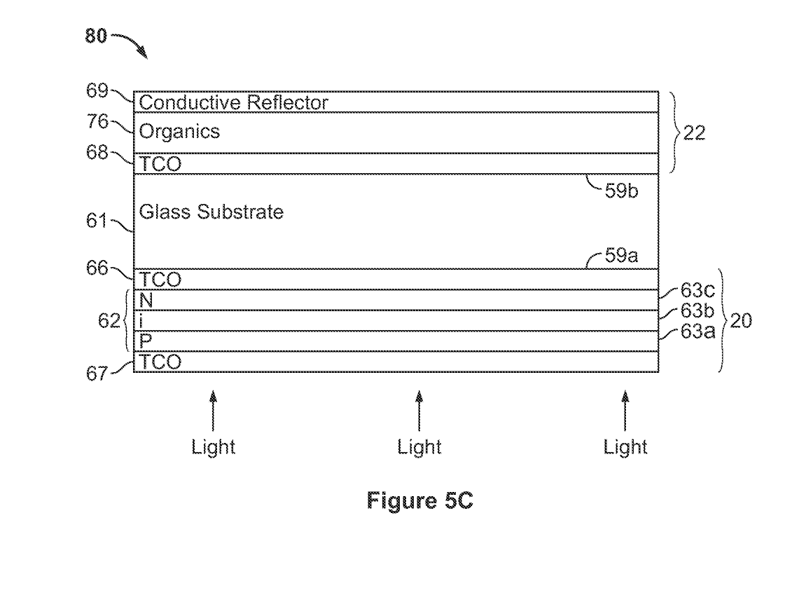

The electrodes 36-39 of the first and second subcells 20, 22 can be similar to the first and second electrodes 4, 6 described above with reference to FIG. 1. One or more of the electrodes 36-39 can be transparent conductors, such as transparent conductive oxide (TCO) structures. However, as will be described further below with reference to FIG. 5A, in some implementations the fourth electrode 39 can include a reflective layer, such as aluminum (Al) or silver (Ag), which can be configured to reflect light that passes through the first and second photovoltaic subcells 20, 22 back toward the first and second photovoltaic subcells 20, 22.

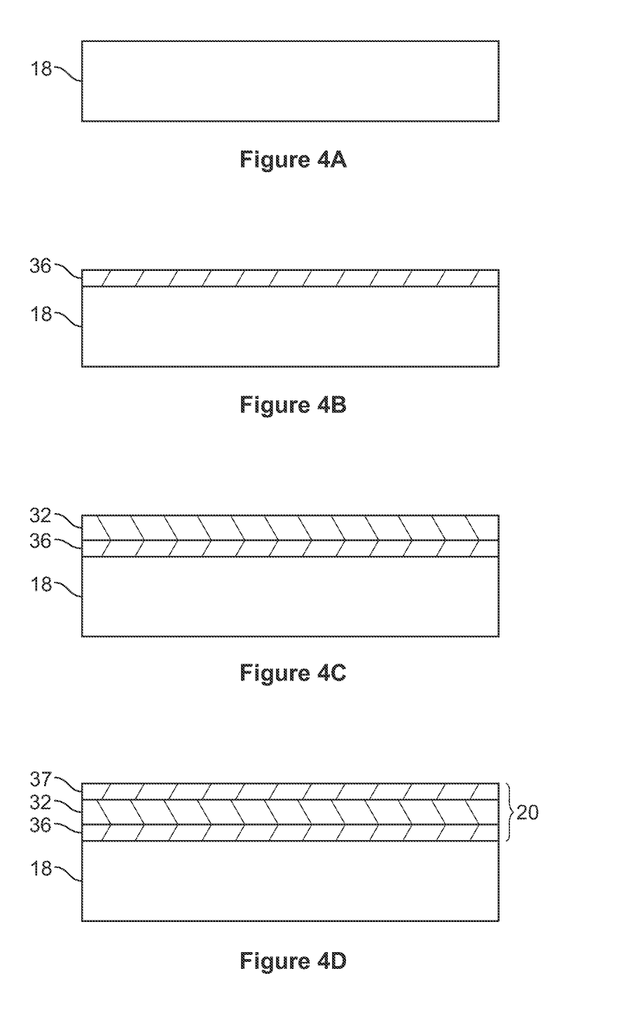

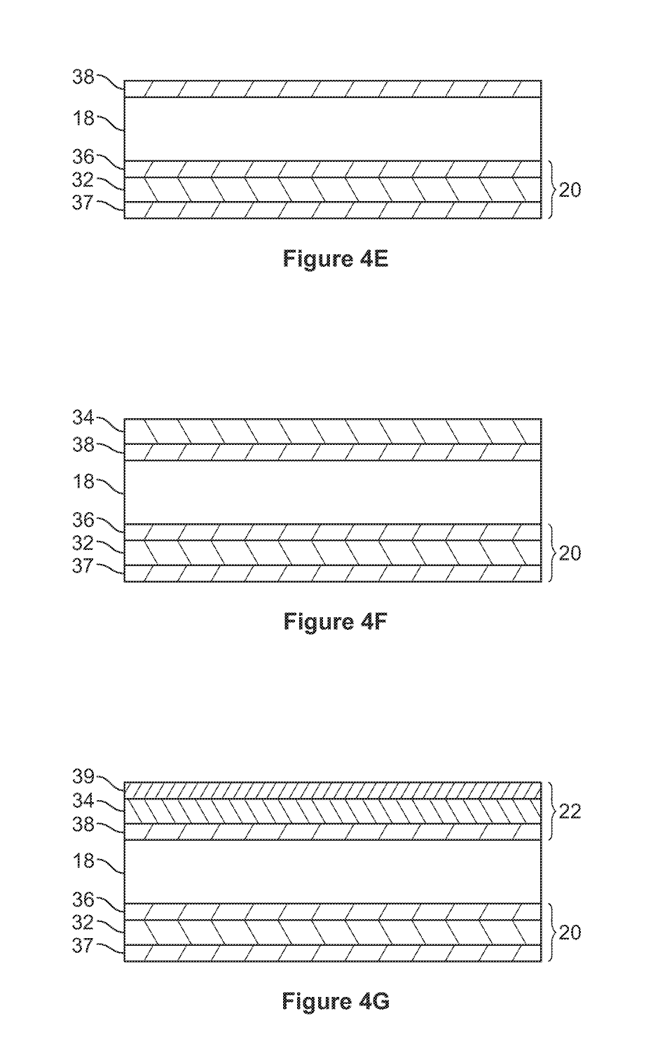

The transparent substrate 18 can be a glass substrate or any other suitable transparent substrate, such as an optical plastic. The transparent substrate 18 can be employed to structurally support the first and second photovoltaic subcells 20, 22. Additionally, as will be described in detail below with reference to FIG. 4A-4G, the photovoltaic device 30 can be formed using thin film technology, and the first and second subcells 20, 22 can be formed from a plurality of thin film layers deposited on opposing surfaces of the transparent substrate 18.

The transparent substrate 18 can aid in chemically isolating the first and second subcells 20, 22 during manufacture, thereby permitting the subcells to include materials which can chemically interact when in contact and/or which are manufactured using different chemistries. For example, the transparent substrate 18 can include a relatively chemically inert material, such as glass or plastic, and can have a thickness sufficient to chemically isolate opposing sides of the transparent substrate, such as a thickness ranging between about 0.1 mm to about 10 mm. Accordingly, including the transparent substrate 18 can allow a wider selection of materials that can be used in forming the photovoltaic device 30 relative to certain other photovoltaic devices, for example conventional tandem junction cells, which can have material limitations due to certain chemical interactions between subcells and/or conflicting process requirements during manufacture. Accordingly, the first and second photovoltaic subcells 32, 34 can each be chosen from a wide selection of light absorbing photovoltaic materials, including, for example, crystalline silicon (c-silicon), amorphous silicon (a-silicon), cadmium telluride (CdTe), copper indium diselenide (CIS), copper indium gallium diselenide (CIGS), III-V semiconductors, and/or organics such as light absorbing small molecular weight dyes and polymers. The material for the photovoltaic structure can be chosen depending on the desired performance and the application of the photovoltaic device 30. For example, the first and second subcells 20, 22 can be formed from materials having absorption spectrums that are complimentary, as will be described in further detail below.

The first and second photovoltaic subcells 20, 22 of FIG. 2A can operate as first and second photodiodes 42, 44, respectively. Since the first and second photovoltaic subcells 20, 22 each include a separate pair of electrodes, the first and second photovoltaic subcells 20, 22 can provide independent electrical operation. For example, the first photovoltaic subcell 20 can generate a first photocurrent and the second photovoltaic subcell 22 can generate a second photocurrent, and the first and second photocurrents can be combined and delivered to a load.

With continuing reference to FIG. 2A, the photovoltaic device 30 can provide improved power efficiency relative to conventional tandem junction photovoltaic devices, which can include a plurality of subcells electrically connected end-to-end in series, with each subcell having an absorption spectrum that is optimized for a partial band of light. As a person having ordinary skill in the art will appreciate, a tandem junction photovoltaic device can have a total photocurrent limited by the smallest photocurrent generated by a subcell. Even if the subcells of a tandem junction photovoltaic device are designed to have a current that is about equal under a typical white light condition, such as the AM1.5G standard reference spectrum, the tandem junction photovoltaic device can have an overall current constrained by a subcell current when lighting conditions deviate from a norm. For example, in early morning, late afternoon, or in high latitude areas, sun light can include more red light relative to light conditions used in design, which can lead to an imbalance in subcell photocurrents and a reduction in power efficiency of a tandem junction photovoltaic device.

In contrast, the first and second subcells 20, 22 of the illustrated photovoltaic device 30 can generate independent photocurrents, which can be combined and delivered to a load, thereby avoiding limiting the current of the photovoltaic device 30 to the smallest subcell photocurrent. For example, in certain implementations, when the first photovoltaic subcell 20 has a fill-factor FF₁, an open-circuit voltage V_{OC1} and a photocurrent I₁, and the second photovoltaic subcell 22 has a fill-factor FF₂, an open-circuit voltage V_{OC2} and a photocurrent I₂, the overall power P provided by the photovoltaic device 30 can be given by equation 1 below.

P=I₁*V_{OC1}*FF₁+I₂*V_{OC2}*FF₂ (1)

The photovoltaic device 30 of FIG. 2A can also provide additional advantages over tandem junction photovoltaic devices. For example, the photovoltaic device 30 can be manufactured without forming a tunnel junction at the interface between subcells, thereby improving ease of manufacture and increasing device yield.

FIG. 2B shows a graph 50 of one example of quantum efficiency versus wavelength for a photovoltaic device including first and second photovoltaic subcells. The graph 50 includes a first absorption spectrum 51 of the first photovoltaic subcell and a second absorption spectrum 52 of the second photovoltaic subcell.

In FIG. 2B, the first and second absorption spectra 51, 52 can correspond to absorption spectra of the first and second photovoltaic subcells 20, 22 of FIG. 2A. The first and second absorption spectra 51, 52 can be complimentary and include peak quantum efficiencies at different wavelengths of light. Providing first and second subcells having complimentary absorption spectra permits a photovoltaic device with such subcells to have a broadened total absorption spectra and an overall increased power efficiency. For example, the overall efficiency of a device that includes such first and second photovoltaic subcells 20, 22 can correspond to the cumulative area under the curves of the first and second absorption spectra 51, 52.

In one implementation, a photovoltaic device includes a first subcell and a second subcell, the first subcell having an absorption spectrum with a quantum efficiency greater than about 50% at a wavelength ranging between about 350 nm and about 600 nm, and the second subcell having an absorption spectrum with a quantum efficiency greater than about 50% at a wavelength ranging between about 600 nm and about 800 nm.

As described above with reference to FIG. 2A, photovoltaic devices can include a transparent substrate and subcells positioned on opposing surfaces of the transparent substrate, thereby permitting the manufacture of first and second subcells 20, 22 having vastly different chemistries. Allowing a broader selection of manufacturing materials for the first and second subcells, including, for example, selection of an inorganic material for the first subcell and an organic material for the second subcell, can aid in making the absorption spectra of the subcells wider and/or more complimentary relative to existing tandem junction solar cells.

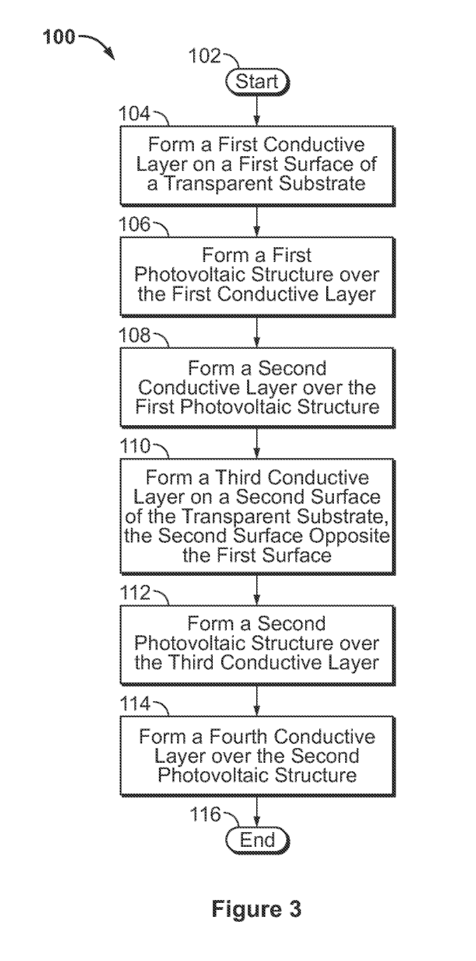

FIG. 3 shows an example of a flow diagram illustrating a manufacturing process for a photovoltaic device. The process 100 starts at 102. In block 104, a first conductive layer is formed on a first surface of a transparent substrate. The transparent substrate can include, for example, glass or plastic. Although the process 100 is illustrated as starting at block 102, the transparent substrate can be subjected to one or more prior preparation steps such as a cleaning step to facilitate efficient formation of the first conductive layer.

The first conductive layer can be any suitable conductor, including, for example, a transparent conductive oxide (TCO) structure such as tin oxide (SnO₂), zinc oxide (ZnO) and/or indium tin oxide (ITO). Selecting the first conductive layer to be a transparent conductor, such as a TCO structure, can permit more light to pass through the first conductive layer relative to a scheme in which the layer is optically opaque and includes one or more openings for passing light. In one implementation, the first conductive layer has a thickness ranging between about 50 nm to about 5000 nm.

Formation of the first conductive layer may be carried out using deposition techniques, including, for example physical vapor deposition (PVD, e.g., sputtering), chemical vapor deposition (CVD), electrochemical vapor deposition (EVD), or pyrolysis. Forming the first conductive layer can include patterning the conductive layer to form desired electrical connectivity of the photovoltaic device. As used herein, and as will be understood by a person having ordinary skill in the art, the term “patterned” is used to refer to masking as well as etching processes.

The process 100 illustrated in FIG. 3 continues at block 106, in which a first photovoltaic structure is formed over the first conductive layer. The first photovoltaic structure can be any suitable photovoltaic structure, including, for example, an amorphous silicon (a-Si)/microcrystalline Si (μc-Si) structure, a cadmium telluride/cadmium selenium (CdTe/CdS) structure, an organic structure, a copper indium gallium selenide (CIGS) structure, or any of the photovoltaic structures described earlier. The first photovoltaic structure can be formed using thin film manufacturing techniques, including one or more deposition and patterning steps, such as those described above. In one implementation, the first photovoltaic structure has a thickness ranging between about 50 nm and about 10 μm.

In a block 108, a second conductive layer is formed over the first photovoltaic structure. As will be described below, the second conductive layer can be configured to be transparent to ambient light. The second conductive layer can be, but need not be, similar to the first conductive layer formed in block 104. In one implementation, the second conductive layer has a thickness ranging between about 50 nm to about 5000 nm.

The first conductive layer, the first photovoltaic structure, and the second conductive layer collectively form a first photovoltaic subcell disposed on the first surface of the transparent substrate. The first and second conductive layers can operate as electrodes of the first photovoltaic subcell.

With continuing reference to FIG. 3, the process 100 continues at block 110, in which a third conductive layer is formed on a second surface of the transparent substrate opposite the first surface. The second surface of the transparent substrate can be cleaned or otherwise processed to aid in forming the third conductive layer. Additional details of the third conductive layer can be similar to those described above with respect to the first and second conductive layers.

In a block 112, a second photovoltaic structure is formed over the third conductive layer. The second photovoltaic structure can be any of a wide variety of photovoltaic structures, including, for example, an amorphous silicon (a-Si) structure, a cadmium telluride/cadmium selenium (CdTe/CdS) structure, an organic structure, a copper indium gallium selenide (CIGS) structure, or any of the photovoltaic structures described earlier. The second photovoltaic structure can be formed using thin film processing techniques. Additionally, the characteristics of the second photovoltaic structure, such as the material composition, can be selected so that the second photovoltaic structure has an absorption spectrum that is complimentary to the absorption spectrum of the first photovoltaic structure, thereby enhancing the overall optical absorption of the photovoltaic device. In one implementation, the second photovoltaic structure has a thickness ranging between about 50 nm and about 10 μm.

The process 100 illustrated in FIG. 3 continues at block 114, in which a fourth conductive layer is formed over the second photovoltaic structure. The fourth conductive layer can be similar to the first, second and third conductive layers described earlier. However, in certain implementations, the fourth conductive layer is a reflective layer that can reflect light back toward the first and second photovoltaic structures, as will be described in detail later below. The third conductive layer, the second photovoltaic structure, and the fourth conductive layer collectively form a second photovoltaic subcell disposed on the second surface of the transparent substrate. The third and fourth conductive layers can operate as electrodes of the second photovoltaic subcell. The method is illustrated as ending at 116, however, other subsequent steps may also be performed.

FIGS. 4A-4G show examples of cross-sectional schematic illustrations of various stages of making a photovoltaic device.

FIG. 4A illustrates a transparent substrate 18 which is provided for making a photovoltaic device. The transparent substrate 18 can include glass, plastic or any transparent polymeric material which permits light to pass through the substrate and which is electrically insulating.

FIGS. 4B-4D illustrate forming a first photovoltaic subcell 20 on a surface of the transparent substrate 18. In FIG. 4B, a first conductive layer or first electrode 36 has been formed on the surface of the transparent substrate 18. In FIG. 4C, a first photovoltaic structure 32 has been formed over the first conductive layer 36. FIG. 4D illustrates forming a second conductive layer or second electrode 37 over the first photovoltaic structure 32. The first and second conductive layers 36, 37 operate as first and second electrical terminals of the first photovoltaic subcell 20.

FIGS. 4E-4G illustrate forming a second photovoltaic subcell 22 on a surface of the transparent substrate 18 opposite to the first photovoltaic subcell 20. In FIG. 4E, a third conductive layer or third electrode 38 has been formed on the transparent substrate 18. In FIG. 4F, a second photovoltaic structure 34 has been formed over the third conductive layer 38. FIG. 4G illustrates forming a fourth conductive layer or fourth electrode 39 over the second photovoltaic structure 34. The third and fourth conductive layers 38, 39 operate as first and second electrical terminals of the second photovoltaic subcell 20.

The first and second subcells 20, 22 can be formed using thin film techniques, such as deposition processes employing physical vapor deposition (PVD), chemical vapor deposition (CVD), electro-chemical vapor deposition (EVD) and/or plasma enhanced chemical vapor deposition (PE-CVD). The thin film photovoltaic subcells 20, 22 can include amorphous, monocrystalline, or polycrystalline materials, including, for example, silicon, copper indium selenide (CIS), cadmium telluride (CdTe) or copper indium gallium selenide (CIGS). Providing the first and second subcells 20, 22 on opposite surfaces of a transparent substrate permits formation of subcells that are electrically and chemically independent, thus permitting a broader selection of manufacturing materials and avoiding the need to form a tunnel junction between subcells. Additional details of the first and second subcells 20, 22 can be as described earlier.

FIGS. 5A-5C show examples of cross-sections of varying implementations of photovoltaic devices.

FIG. 5A shows an example of a photovoltaic device 60 including a first photovoltaic subcell 20 disposed on a first surface 59a of a glass substrate 61 and a second photovoltaic subcell 22 disposed on a second surface 59b of the glass substrate 61 opposite the first surface 59a.

The first photovoltaic subcell 20 includes a first transparent conductive oxide (TCO) structure 66 positioned adjacent to the first surface 59a of the glass substrate 61, a first photovoltaic structure 62 disposed adjacent to the first TCO structure 66, and a second TCO structure 67 positioned adjacent to the first photovoltaic structure 62 and on the opposite side of the first photovoltaic structure 62 than the first TCO structure 66. The first and second TCO structures 66, 67 can be configured as electrodes of the first photovoltaic subcell 20.

The second photovoltaic subcell 22 includes a third TCO structure 68 positioned adjacent to the second surface 59b of the glass substrate 61, a second photovoltaic structure 64 disposed adjacent to the third TCO structure 68, and a conductive reflector 69 positioned adjacent to the second photovoltaic structure 64 and on the opposite side of the second photovoltaic structure 64 as than the third TCO structure 68. The third TCO structure 68 and the conductive reflector 69 can be configured as electrodes of the second photovoltaic subcell 22.

The first photovoltaic structure 62 shown in FIG. 5A is a p-i-n junction including a p-type layer 63a, an intrinsic layer 63b, and an n-type layer 63c. The intrinsic layer 63b is positioned between the p-type layer 63a and the n-type layer 63b. The p-i-n junction can be, for example, an amorphous silicon (a-Si) structure or microcrystalline (μc-Si) structure. A p-i-n junction can have a depletion region that is larger than a depletion region of a p-n junction, which can aid in increasing the light absorption and the magnitude of the photocurrent generated by the photovoltaic subcell. For example, electron-hole pairs generated by light photons within or near the depletion region can be swept by the electric field of the depletion region to create the photocurrent, and thus a depletion region of a larger size can lead to an increase in the magnitude of the photocurrent. In one implementation, the second photovoltaic structure 64 has a thickness ranging between about 50 nm and about 500 nm.

In the implementation illustrated in FIG. 5A, the second photovoltaic structure 64 is a heterojunction structure including a cadmium selenium (CdS) layer 65a and a cadmium tellurium (CdTe) layer 65b. Heterojunction photovoltaic structures can have improved quantum efficiencies relative to homojunction photovoltaic structures. For example, the CdTe layer 65b can have a bandgap that is greater than a bandgap of the CdS layer 65a, and can be positioned so as to receive a portion of light before it reaches the CdS layer 65a. Thus, the CdTe layer 65b can absorb a portion of relatively high energy light before it reaches the CdS layer 65a. Since photon energy exceeding the bandgap energy can be dissipated as heat, providing the CdTe layer 65b to absorb light of a relatively high energy before it reaches the CdS layer 65a layer can aid in increasing the quantum efficiency of the photovoltaic structure by reducing the amount of energy lost as heat. In one implementation, the second photovoltaic structure 64 has a thickness ranging between about 1 μm and about 10 μm.

Still referring to FIG. 5A, the first photovoltaic subcell 20 of the photovoltaic device 60 is configured to receive light that enters the photovoltaic device 60. For example, the second TCO structure 67 can include a surface of the photovoltaic device 60 that receives incident light. A portion of the incident light 54a can be absorbed by the first photovoltaic structure 62. Additionally, a portion of the light 54b can pass through the first photovoltaic subcell 20 and the glass substrate 61 and can be absorbed by the second photovoltaic structure 64.

To increase the overall amount of light absorbed by the photovoltaic device 60, the second photovoltaic subcell 22 can include the conductive reflector 69 for reflecting light back toward the first and second photovoltaic subcells 20, 22. The conductive reflector 69 can increase the overall efficiency of the photovoltaic device 60. For example, a portion of light 54c can pass through the first and second photovoltaic subcells 20, 22, and can thereafter be reflected by the conductive reflector 69 and absorbed by the second photovoltaic structure 64. Similarly, a portion of light 54d can pass through the first and second photovoltaic subcells 62, 64, and can thereafter be reflected by the conductive reflector 69 and absorbed by the first photovoltaic structure 62. Thus, the conductive reflector 69 can increase the efficiency of the photovoltaic device 60 by increasing the amount of light absorbed by the first and second photovoltaic subcells 20, 22.

FIG. 5B shows an example of a photovoltaic device 70 including a first photovoltaic subcell 20 formed on a first surface 59a of a glass substrate 61 and a second photovoltaic subcell 22 formed on a second surface 59b of the glass substrate 61 opposite the first surface 59a.

The first photovoltaic subcell 20 includes a first transparent conductive oxide (TCO) structure 66 adjacent the first surface 59a of the glass substrate 62, a first photovoltaic structure 62 disposed adjacent the first TCO structure 66, and a second TCO structure 67 for receiving light and disposed adjacent the first photovoltaic structure 62 opposite the first TCO structure 66. The first and second TCO structures 66, 67 can operate as electrodes of the first photovoltaic subcell 20. The illustrated first photovoltaic structure 62 is a p-i-n junction including a p-type layer 63a, an intrinsic layer 63b, and an n-type layer 63c, as was described above with respect to FIG. 5A.

The second photovoltaic subcell 22 includes a third TCO structure 68 adjacent the second surface 59b of the glass substrate 61, a second photovoltaic structure 74 adjacent the third TCO structure 68, and a conductive reflector 69 adjacent the second photovoltaic structure 74 opposite the third TCO structure 68.

The second photovoltaic structure 74 shown in FIG. 5B is a heterojunction structure including a cadmium selenium (CdS) layer 75a disposed adjacent the third TCO structure 68 and a cadmium copper indium gallium selenide (CuInₓGa₁₋ₓSe) or CIGS layer 75b disposed between the conductive reflector 69 and the CdS layer 75a. Heterojunction photovoltaic structures can have improved quantum efficiencies, as was described above. In one implementation, the second photovoltaic structure 74 has a thickness ranging between about 1 μm to about 5 μm.

FIG. 5C shows an example of a photovoltaic device 80 including a first photovoltaic subcell 20 formed on a first surface 59a of a glass substrate 61 and a second photovoltaic subcell 22 formed on a second surface 59b of the glass substrate 61 opposite the first surface 59a. The first photovoltaic subcell 20 includes a first transparent conductive oxide (TCO) structure 66, a second TCO structure 67 for receiving light, and a first photovoltaic structure 62 including a p-type layer 63a, an intrinsic layer 63b, and an n-type layer 63c, as was described above with respect to FIG. 5A.

The second photovoltaic subcell 22 includes a third TCO structure 68 adjacent the second surface 59b of the glass substrate 61, a second photovoltaic structure 76 adjacent the third TCO structure 68, and a conductive reflector 69 adjacent the second photovoltaic structure 76 opposite the third TCO structure 68.

The second photovoltaic structure 76 is an organic photovoltaic structure, such as a structure including polymers and/or small molecular weight dyes. In one implementation, the second photovoltaic structure has a thickness ranging between about 50 nm to about 1000 nm. As illustrated in FIG. 5C, providing first and second photovoltaic cells 20, 22 on opposite surfaces of a substrate permits the photovoltaic device to include an inorganic subcell formed on a first surface 59a of a substrate and an organic subcell formed on a second surface 59b of the substrate.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A solar cell device comprising:
a transparent insulator;
a thin film first solar subcell disposed on a first surface of the transparent insulator, the first solar subcell configured to receive ambient light; and
a thin film second solar subcell disposed on a second surface of the transparent insulator, the second surface on an opposite side of the transparent insulator than the first surface, the second solar subcell configured to receive a portion of light that propagates through the first solar subcell, the second solar subcell comprising a first electrode including a conductive reflective layer configured to reflect light that propagates through a photovoltaic structure of the second subcell back toward the first solar subcell.

2. The solar cell device of claim 1, wherein the transparent insulator is a glass substrate.

3. The solar cell device of claim 1, wherein the transparent insulator is a plastic substrate.

4. The solar cell device of claim 1, wherein the first solar subcell is characterized by a first absorption spectrum and the second solar subcell is characterized by a second absorption spectrum different from the first absorption spectrum.

5. The solar cell device of claim 1, wherein the transparent insulator prevents chemical reactions between the first and second solar subcells.

6. The solar cell device of claim 1, wherein the first solar subcell includes amorphous silicon and the second solar subcell includes cadmium telluride.

7. The solar cell device of claim 1, wherein the first solar subcell includes an inorganic photovoltaic structure, and wherein the second solar subcell includes an organic photovoltaic structure.

8. The solar cell device of claim 1, wherein the second subcell further comprises a second electrode including a transparent conductive oxide.

9. The solar cell device of claim 1, wherein the first solar subcell includes
a first electrode comprising a first transparent conductive oxide; and
a second electrode comprising a second transparent conductive oxide.

10. A solar power system comprising:
a stack of thin film solar subcells comprising
an optically transparent insulator having a first side and an opposite second side;
a thin film first solar subcell disposed on a first side of the insulator, the first solar subcell including
a first conductive layer defining a first electrical terminal,
a first photovoltaic structure, and
a second conductive layer defining a second electrical terminal,
the first and second electrical terminals contacting opposite sides of the first photovoltaic structure, the first and second electrical terminals configured to provide electrical power generated by the first photovoltaic structure to an external circuit when the first solar subcell is illuminated with light;
a thin film second solar subcell disposed on a second side of the insulator, the second solar subcell comprising
a third conductive layer defining a third electrical terminal,
a second photovoltaic structure, and
a fourth conductive layer defining a fourth electrical terminal, the third and fourth electrical terminals contacting opposite sides of the second photovoltaic structure, the third and fourth electrical terminals configured to provide electrical power generated by the second photovoltaic structure when the second solar subcell is illuminated with light;
wherein the insulator is optically transparent to a portion of light absorbed by the second solar subcell.

11. The system of claim 10, wherein the fourth conductive layer includes a reflective surface that is disposed to reflect light that passes through the second solar subcell back towards the second solar subcell.

12. The system of claim 10, wherein the transparent insulator comprises a glass substrate.

13. The system of claim 10, wherein the transparent insulator comprises a plastic substrate.

14. The system of claim 10, wherein the first solar subcell is characterized by a first absorption spectrum and the second solar subcell is characterized by a second absorption spectrum different from the first absorption spectrum.

15. The system of claim 14, wherein the first absorption spectrum covers a first band of visible light and the second absorption spectrum covers a second band of visible light, the first and second absorption spectrums complimenting each other such that a combined absorption spectrum of the first and second absorption spectrums covers a greater portion of the band of visible light than either the first absorption spectrum or the second absorption spectrum.

16. The system of claim 15, wherein the second absorption spectrum further covers a band of infrared light.

17. The system of claim 10, wherein the transparent insulator prevents chemical reactions between the first and second solar subcells.

18. The system of claim 10, wherein the first solar subcell comprises amorphous silicon and the second solar subcell comprises cadmium telluride.

19. The system of claim 10, wherein the first solar subcell comprises an inorganic photovoltaic structure, and wherein the second solar subcell comprises an organic photovoltaic structure.

20. A method of forming a thin film solar cell device, the method comprising:
forming a first conductive layer on a first surface of a transparent substrate;
forming a first photovoltaic structure over the first conductive layer;
forming a second conductive layer over the first photovoltaic structure;
forming a third conductive layer on a second surface of the transparent substrate, the second surface on an opposite side of the transparent substrate than the first surface;
forming a second photovoltaic structure over the third conductive layer; and
forming a fourth conductive layer over the second photovoltaic structure.

21. The method of claim 20, wherein the fourth conductive layer is configured to reflect light that propagates through the second photovoltaic structure back towards the first photovoltaic structure.

22. The method of claim 21, wherein the first, second and third conductive layers are transparent conductive oxides.

23. The method of claim 20, wherein the transparent substrate comprises glass.

24. The method of claim 20, wherein the transparent substrate comprises plastic.

25. The method of claim 20, wherein the first photovoltaic structure is characterized by a first absorption spectrum and the second photovoltaic structure is characterized by a second absorption spectrum different from the first absorption spectrum.

26. The method of claim 25, wherein the first photovoltaic structure is a p-i-n photovoltaic structure.

27. The method of claim 26, wherein the second photovoltaic structure comprises a CdTe layer having a p-type doping and a CdS layer having an n-type doping.

28. The method of claim 26, wherein the second photovoltaic structure comprises a copper indium gallium selenide (CIGS) photovoltaic structure.

29. The method of claim 26, wherein the second photovoltaic structure comprises an organic photovoltaic structure.

30. A solar cell device comprising:
a transparent insulator including a first and second surface, the second surface on an opposite side of the transparent insulator than the first surface;
a first means for receiving ambient light, the first light receiving means including a thin film solar subcell disposed on the first surface of the transparent insulator; and
a second means for receiving ambient light, the second light receiving means including a thin film second solar subcell disposed on the second surface of the transparent insulator and configured to receive a portion of light that propagates through the first light receiving means, the second light receiving means comprising a first reflective electrode configured to reflect light that propagates through the photovoltaic structure of the second light receiving means back toward the first light receiving means.

31. The solar cell device of claim 30, wherein the first light receiving means is characterized by a first absorption spectrum and the second light receiving means is characterized by a second absorption spectrum different from the first absorption spectrum.

32. The solar cell device of claim 31, wherein the first absorption spectrum covers a first band of visible light and the second absorption spectrum covers a second band of visible light, the first and second absorption spectrums complimenting each other such that a combined absorption spectrum of the first and second absorption spectrums covers a greater portion of the band of visible light than either the first absorption spectrum or the second absorption spectrum.
